(19) United States
(12) Patent Application Publication
(10) Pub. No.: US 2025/0321279 A1
(43) Pub. Date: Oct. 16, 2025

(54) METHODS, APPARATUS, AND SYSTEMS FOR GENERATING COMPUTATIONAL ELECTRODYNAMIC PARAMETERS OF AN ELECTROCHEMICAL SYSTEM

(71) Applicant: Iontra Inc, Centennial, CO (US)

(72) Inventors: Zhong WANG, Sugar Land, TX (US); Alan GHAZARIANS, San Diego, CA (US); Alon ROSENBERG, Boulder, CO (US); Chris MORRONI, Denver, CO (US); Daniel A. KONOPKA, Aurora, CO (US); Manoj K. KOUL, Allen, TX (US)

(21) Appl. No.: 19/177,291

(22) Filed: Apr. 11, 2025

Related U.S. Application Data
(60) Provisional application No. 63/633,579, filed on Apr. 12, 2024.
(60) Provisional application No. 63/648,610, filed on May 16, 2024.

(51) Int. Cl. G01R 31/367; G01R 31/36

(52) U.S. Cl. CPC G01R 31/367; G01R 31/3648

(57) ABSTRACT

Methods, systems, and devices are disclosed for calculating parameters, such as electrodynamic parameters of a battery or other electrochemical system. A system includes a sequencing, programmable core (e.g., a central processing unit (CPU)) or other digital logic which is used to control a state machine of the system. One or more digital logic accelerators (e.g., co-processor or math co-processor) blocks may be used in operable communication with at least one accelerator module, wherein the at least one accelerator module is configured to provide an input to the CPU that is used in calculating the electrodynamic parameter of the battery.

### CROSS-REFERENCE TO RELATED APPLICATIONS

This application claims priority to U.S. Provisional Patent Application No. 63/633,579, filed Apr. 12, 2024, entitled “METHODS, APPARATUS, AND SYSTEMS FOR GENERATING COMPUTATIONAL ELECTRODYNAMIC PARAMETERS OF AN ELECTROCHEMICAL SYSTEM,” and to U.S. Provisional Patent Application No. 63/648,610, filed May 16, 2024, entitled “METHODS, APPARATUS, AND SYSTEMS FOR GENERATING COMPUTATIONAL ELECTRODYNAMIC PARAMETERS OF AN ELECTROCHEMICAL SYSTEM,” the entire disclosures of which are hereby incorporated by reference, for all purposes, as if fully set forth herein.

### TECHNICAL FIELD

Embodiments of the present invention generally relate to systems and methods for fast, energy efficient, lower logic area and/or higher throughput data processing using digital logic, software, and/or computation techniques for calculating parameters, such as electrodynamic parameters, and for performing mathematical functions. In some embodiments, the mathematical functions relate to computational chemistry.

### Background and Introduction

Battery powered devices have proliferated and become ubiquitous. Device manufacturers are constantly pressing for performance improvement in batteries, particularly as batteries are introduced into devices with relatively higher current demands and power needs. At the same time, consumers demand longer battery life, longer times between charges, and shorter charge times. As such, there is an ongoing and continuous need for improvements in how batteries are managed, charged, and discharged to enhance performance. It is with these observations in mind, among others, that aspects of the present disclosure were conceived.

### SUMMARY

Methods, systems, and devices are disclosed for calculating parameters, such as electrodynamic parameters of a battery or other electrochemical system. A system includes a sequencing, programmable core (e.g., a central processing unit (CPU)) or other digital logic which is used to control a state machine of the system. One or more digital logic accelerators (e.g., co-processor or math co-processor) blocks may be used in operable communication with at least one accelerator module, wherein the at least one accelerator module is configured to provide an input to the CPU that is used in calculating the electrodynamic parameter of the battery.

### BRIEF DESCRIPTION OF THE DRAWINGS

FIG. 1 is a block diagram of a digital logic accelerator (e.g., co-processor) system, in accordance with some embodiments.

FIG. 2 is an example of a data set with the data divided into overlapping windows, in accordance with some embodiments.

FIG. 3A is a block diagram showing steps involved in short time transform methods, in accordance with some embodiments.

FIG. 3B is a diagram demonstrating an input buffer divided into a plurality of overlapping windows, in accordance with some embodiments.

FIG. 4 is a chart demonstrating different sample and memory sizes and requirements associated with different short time transforms, in accordance with some embodiments.

FIG. 5 is a diagram demonstrating the generation of a trajectory matrix from an input data vector, in accordance with some embodiments.

FIG. 6 is a diagram demonstrating the generation of an indexed distance array, in accordance with some embodiments.

FIGS. 7A-7C show nearest neighbor results based on different minimum separation thresholds, in accordance with some embodiments.

FIG. 8 shows block diagrams for determining a nearest and/or farthest neighbor for an orbit and for saving the nearest and/or farthest neighbor, in accordance with some embodiments.

FIG. 9 is a block diagram showing access, inputs, and outputs to memory within an accelerator system, in accordance with some embodiments.

FIG. 10 is a block diagram showing steps involved in a time expansion process, in accordance with some embodiments.

FIG. 11 is a block diagram of a control system implemented with a system on chip, an application-specific micro-controller unit (MCU) or other integrated circuit (IC), in accordance with some embodiments.

### DETAILED DESCRIPTION

Aspects of the present disclosure involve a hardware- and/or software-based accelerator (e.g., co-processor) system capable of quickly calculating complex characterization parameters or mathematical functions using electrical measurements. In some embodiments, the electrical measurements are taken from an electrochemical system (e.g., a battery cell or battery pack) and the characterization parameters are electrodynamic parameters based on the electrical measurements. Calculating complex parameters requires significant time and resources (e.g., memory) and as a result, has not been practical to perform on a chip in an efficient and cost-effective manner. A device, system, and method for calculating parameters quickly (e.g., in real-time) without committing expensive resources to the task are needed so that the calculation of complex electrodynamic parameters can be completed on a chip for use as an input to a control system (e.g., a battery management system) responsible for controlling charging and discharging of a battery. The computation of the complex electrodynamic parameters may also be used to characterize a battery's response to charge and discharge currents and develop various charging protocols that may or may not be used in a feedback-based control environment. Control of battery charging and discharging that is based on detected processes occurring within the battery may improve charge speed, improve battery capacity, and may reduce degradation of the battery over time, thereby leading to longer battery life and improved user experience. In some embodiments, multiple co-processor blocks may be used to perform computations many times faster than a normal CPU or graphics processing unit (GPU). In some embodiments, a CPU may offload computations to purpose-built hardware co-processor blocks (e.g., a single or multiple copies of the co-processor blocks). These and other advantages will be understood from the discussion that follows.

Initially, the term “battery” in the art and herein can be used in various ways and may refer to an individual cell having an anode and cathode separated by an electrolyte as well as a collection of such cells connected in various arrangements. Further, the terms charging and recharging are used synonymously herein. A battery or battery cell is a form of electrochemical device. Batteries generally comprise repeating units of sources of a countercharge and first electrode layers separated by an ionically conductive barrier, often a liquid or polymer membrane saturated with an electrolyte but may also be a solid electrolyte. These layers are made to be thin so multiple units can occupy the volume of a battery, increasing the available power of the battery with each stacked unit. Although many examples are discussed herein as applicable to a battery, it should be appreciated that the systems and methods described may apply to many different types of batteries ranging from an individual cell to batteries involving different possible interconnections of cells such as cells coupled in parallel, series, and parallel and series. For example, the systems and methods discussed herein may apply to a battery pack comprising numerous cells arranged to provide a defined pack voltage, output current, and/or capacity. Moreover, the implementations discussed herein may apply to different types of electrochemical devices such as various different types of lithium batteries including but not limited to lithium-metal and lithium-ion batteries, lead acid batteries, various types of nickel batteries, and solid-state batteries, to name a few. The various implementations discussed herein may also apply to different structural battery arrangements such as cylindrical cells, pouch cells, and prismatic cells. These implementations may also apply to any other electrochemical sensors or systems where an electric current or voltage or other related stimulus is applied to the system to measure properties of the materials.

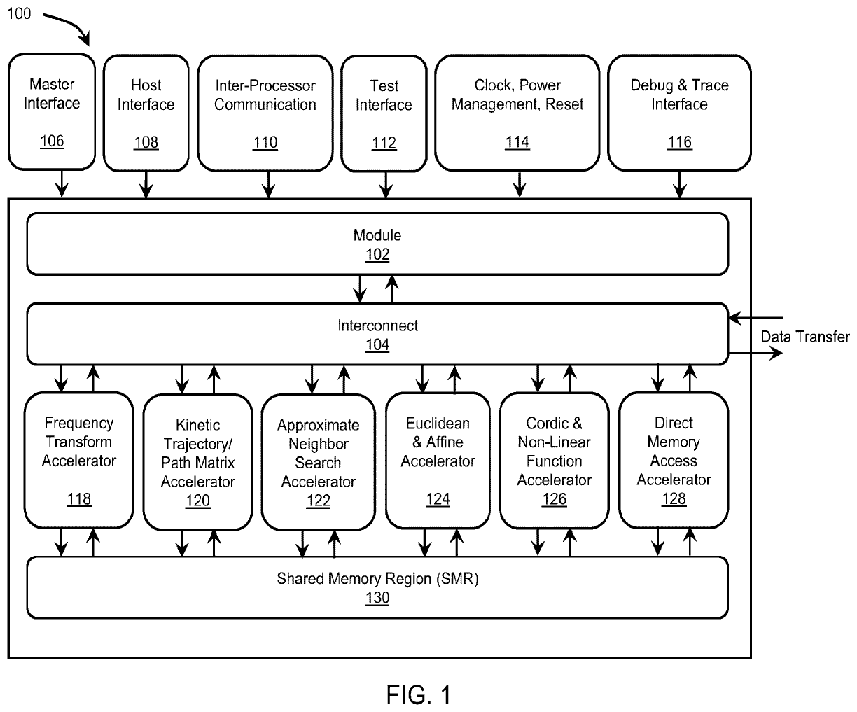

Referring to FIG. 1, an accelerator system 100 includes at least one hardware- and/or software-based computational accelerator (also referred to herein as a co-processor, math co-processor, or primitive) configured to enable the computation of electrodynamic parameters within a cost-effective budget. The accelerator system may be implemented in application-specific integrated circuits, micro-controllers, or chiplets using chip-to-chip interconnects or other techniques. The system 100 may compute electrodynamic parameters for an electrochemical system (e.g., a battery), the parameters including one or more of a Residual Vector Energy Separation Index (RVES) Score or Exponent, a Reduced-Complexity Correlation Dimension (RCCD) Score, a Dynamic Sample Entropy (DSE) Index, a Dispersional Analysis-based Hurst Exponent (DAHE) Score, a Detrended Fluctuation Analysis (DFA) Index, and a Charge Rate Voltage Slew (DIDVS) Score. These parameters may be obtained using optimized algorithms and calculation methods as described herein; however, the underlying mathematics may be the same as those used to calculate a RVES, maximal Lyapunov exponent, correlation dimension, sample entropy, and Hurst exponent, and/or similar electrodynamic parameters. These and/or other parameters may be used by a battery charging system and/or a battery management system to compute State of Health (SOH) of a battery, predict, compute, and/or characterize the onset of a degradation mechanism within the battery, and enact feedback control to prevent (e.g., via modulation of a current carrier, alteration of charge or discharge signal characteristics, alteration of charge current magnitude, addition or alteration of rest periods where no or reduced charge current is applied to the battery, etc.) the progression of the detected degradation. While the following discussion uses an electrochemical system (e.g., a battery charging/management system) as an example to illustrate concepts, other electrical measurements of chemical and/or biological materials or systems may also be supported using the described accelerator system.

Accelerator (co-processor) system 100 includes a module 102 which may be a state machine running on a CPU core (e.g., a RISCV CPU) or a digital logic system. The system 100 further includes co-processor digital blocks (118, 120, 122, 124, 126, 128) that contain logic gates, memory, software, registers, clocks, etc. The co-processor blocks implement functions as described in the block diagram (e.g., frequency transforms, kinetic trajectory/path matrix functions, nearest neighbor searching, Euclidean & affine functions, Cordic and non-linear functions, etc.). The co-processor blocks (e.g., modules 118-128) and the module 102 or other state machine, controller, sequencer, or logic may calculate electrodynamic parameters of a battery under charge, discharge, and/or resting conditions. Data may be transferred from or to the co-processor through DMA block 128 from the main memory either under the control of a main CPU or autonomously once the main CPU activates the state machine of the co-processor system. The co-processor works on data that is on a level 2 memory called Shared Memory Region (SMR) 130. The results are also transferred by the DMA block 128 from the SMR 130 to the main processor or other digital block through DMA ports. The interconnect 104 may be an AHB/AXI interconnect used to allow the control and data signals to flow from the state machine controller/sequencer on module 102, co-processor blocks 118-128, and the main memory. The co-processor is controlled through a master interface 106, and in turn can control a host interface 108, an inter-processor communication channel 110 to communicate between various processors in the system, a test interface 112 for test signaling and production test interface, a clock and power management channel and a reset channel 114, and/or a debug/trace interface 116.

The module 102 may control the calculation of electrodynamic parameters via the interconnect 104. The interconnect 104 is configured to transfer data to/from the module 102 (e.g., CPU, state machine, or digital logic) and to/from one or more accelerator modules. The accelerator modules may include one or more of a Frequency Transform Accelerator 118, a Kinetic Trajectory/Path Matrix Accelerator 120, an Approximate Neighbor Search Accelerator 122, a Euclidean and Affine Accelerator 124, and a Cordic and Non-Linear Function Accelerator 126. The co-processor blocks may have internal memory and registers to work on the data from the SMR 130 and transfer results back into the SMR 130 through the interconnect 104. Additional details about each of the accelerator modules will be provided herein below. Each of the accelerator modules may be configured to provide data to and/or receive data from a shared memory region 130.

While six accelerator modules are illustrated in the system 100, various combinations of the accelerator modules may be used to calculate different electrodynamic parameters. Thus, depending on the desired output electrodynamic parameters, all or only a subset of the illustrated accelerator modules may be included in an accelerator system. Similarly, depending on the desired output electrodynamic parameters, additional accelerator modules may be included to facilitate specific calculations. The electrodynamic parameters that can be computed by the CPU 102 are fundamentally built on top of primitives that the math/signal processing functions can deliver as shown in FIG. 1. Once the desired electrodynamic parameters are calculated, they may be used by a feedback-based charge algorithm to modulate a composited charge, discharge, and/or probing signal that may then be delivered to the battery.

In order to reduce the need for high computational speed and large amounts of memory, optimizations are made in each co-processor (e.g., accelerator module) to deliver the closest mathematically accurate results with certain tradeoffs. The accuracy of these primitives (e.g., calculated parameter values) can either be reduced or increased at the expense of running the system with a faster clock or higher memory (SRAM or otherwise).

### Frequency Transform Accelerator

Each of the accelerator modules described with respect to FIG. 1 are now discussed in further detail, beginning with the Frequency Transform Accelerator (FTA) 118. The FTA 118 can handle a large amount of voltage and/or current data (e.g., voltage or current measurements taken at a terminal of a battery during charge or discharge), or any other electrical measurement data that is of interest. In a battery application, large amounts of data are obtained over long periods of time in order to observe the behavior of the battery. For normal computers or methods, processing this volume of data demands extremely high computational resources and data requirements, and for most use cases, these resource requirements may be impractical or impossible to meet.

When calculating the mean frequency of time domain data, it is common to utilize the Discrete Fourier Transform (DFT) to obtain the frequency domain data. By using the Fast Fourier Transform (FFT), one can significantly speed up the calculation to obtain the frequency domain data. However, when dealing with large-sampled time domain data, the FFT may not prove to be the most memory efficient approach. For example, a FFT of 5,000 samples of 16-bit data can take up to 40 KB of data just to determine the real and imaginary samples of the frequency domain transformed data. In some battery sampling use cases, sample sizes of large FFTs or large Discrete Cosine Transforms (DCT) may be on the order of 10,000-20,000 samples and would demand even more computational and data resources.

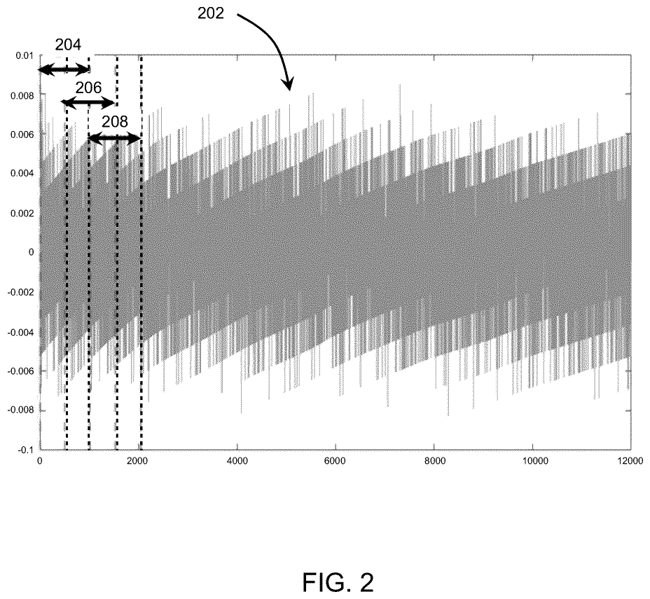

To alleviate demand on memory and digital logic usage, the FTA 118 may use short-time transform (STT) methods, such as the short-time Fourier transform (STFT) and/or short-time discrete cosine transform (STDCT). The STT uses a sliding window, which may include some amount of window overlap, to take more DFTs or FFTs of smaller sampled chunks of time domain data. In particular, the window size determines the size of the sampled time domain data chunk, and the overlap parameter determines how much to overlap the smaller data chunks (e.g., in terms of number of sample points). FIG. 2 shows an example of input data 202 with first, second, and third windows 204, 206, 208, respectively, shown by dashed lines and arrows. The first, second, and third windows have an overlap of approximately 50%, though other overlap ranges may be selected. In some embodiments, overlap may range between 25%-75%. Additional windows may be used to capture additional portions of the sample data 202. Windowing may be performed using Hamming, Hann, Kaiser, or other windowing methodology within the FTA module 118 prior to performing the FFT or the DCT.

Formulaically, the number of FFTs to perform is given by Equation 1 below, and in general, the higher the number of FFTs, the lower the memory usage requirement.

$$number of FFTs = ⌈ \frac{length of data - w indow size}{o v e r l a p} ⌉ + 1. \qquad Eq . 1$$

To calculate the mean frequency using the positive frequencies of the FFT, a power spectrum density (PSD) calculation is performed using Equation 2. Notably, the factor of 2 does not apply to the DC component.

$$P S {D}_{F F T} = \frac{2}{fs \cdot N} {\vert FF T ( data ) \vert}^{2} . \qquad Eq . 2$$

When calculating the PSD using the FFT, a normalization factor may be included because the FFT contains positive and negative frequencies while DCT contains only positive frequencies. The PSD of the DCT may be obtained using Equation 3.

$$P S {D}_{D C T} = \frac{1}{fs \cdot N} {\vert D CT ( data ) \vert}^{2} . \qquad Eq . 3$$

The mean frequency itself is calculated via a frequency weighted sum of as shown in Equation 4 and is the final output of the FTA module 118.

$$mean freq = \frac{\sum freqs \cdot PSD}{\sum PSD} . \qquad Eq . 4$$

When using a short-time method, each chunk of calculated frequency domain data is summed then divided by the number of chunks for normalization purposes. This will produce what is referred to as the PSD above and the mean frequency calculation will follow the same.

The windowing may be implemented with a counter running with a clock. The calculated frequency domain data may be summed suing a floating-point adder which works on the memory of SMR regions as programmed by the state machine controller into its registers. The registers inform the start position and number of data elements that it should operate and number of iterations it must perform.

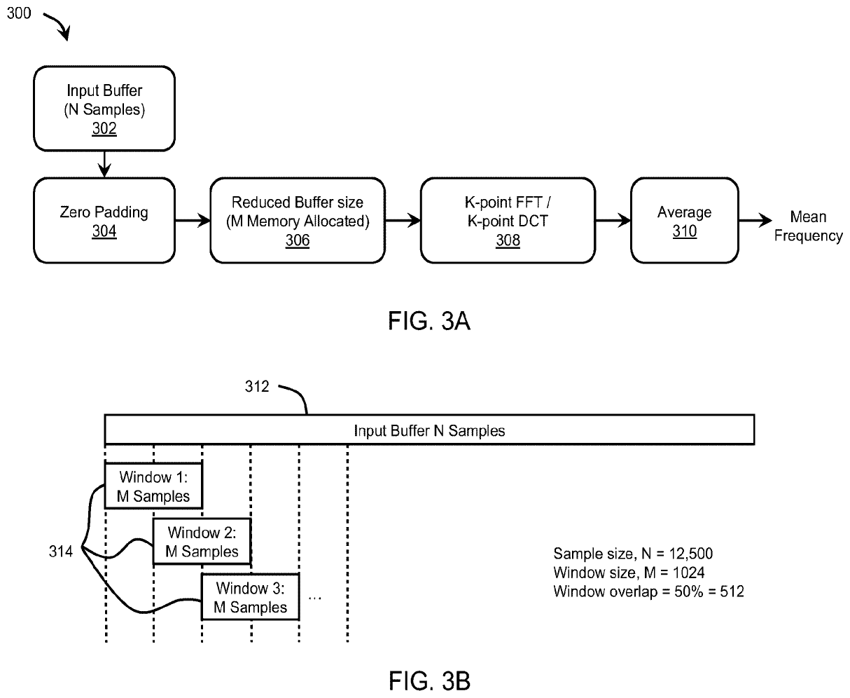

To describe steps of the SST in further detail, an example process 300 is shown in FIG. 3A and a visual representation of input sample data broken down into overlapping windows is shown in FIG. 3B. Sample data having a sample size N is input at step 302. This sample data may be from a stream buffer from an analog-to-digital converter (ADC) input that is provided to the shared memory region 130 (FIG. 1) via direct memory access (DMA) or via the direct memory access accelerator 128. The sample data may represent a long time domain data (single-precision) sample taken at 5 kHz and may have a sample size of N=12,500 points. The total size of the sample data set is represented as box 312 in FIG. 3B.

The input may be zero padded at step 304. The short-time parameter of window size (e.g., memory allocated, M) may be set at step 306. In this example, the memory allocated, M, may correspond to the size of the data chunks or windows and may be set to 1024. The window overlap parameter may also be set; in this example, window overlap is selected to be M/2=512 (e.g., 50% of M). FIG. 3B shows the first three data windows 314 overlapping by 50%, where each of the windows represents a portion of the sample data N, the portion having a size determined by the selected value for M. Remaining data windows are omitted from the figure for clarity. In some embodiments, the value of M and/or the window overlap parameter may be determined or guided by available memory and/or clock speed.

K-point FFTs or K-point DCTs (i.e., an FFT or DCT computation based on each data window) are computed for each data window at step 308 to obtain frequency domain data. The number of FFT or DCT iterations that the FTA 118 must run for the input sample N is given by Equation 1.

Once the iterations are complete, the results are averaged at step 310. In some embodiments, the average is a weighted average as discussed with respect to Equation 4 above. Output from step 310 is a mean frequency value for the input sample N.

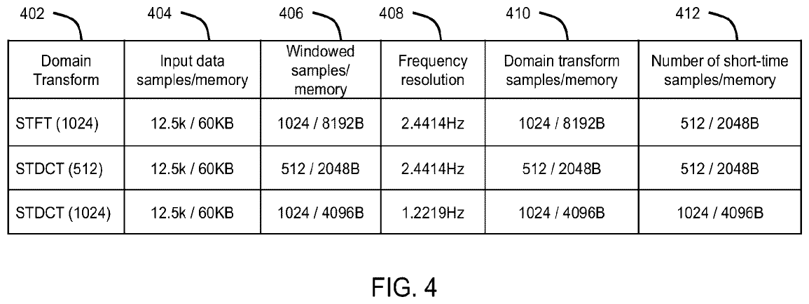

FIG. 4 shows a chart of different domain transforms, their different parameters, and the respective memory needed to calculate the mean frequency. Column 402 shows the type of domain transform and the allocated memory M (e.g., the selected window size). Column 404 shows input data sample size (e.g., 12,500 in this example) and its memory usage (e.g., 60 KB). Column 406 shows the allocated memory M (e.g., the selected window size) and its required memory. Column 408 shows the frequency resolution, column 410 shows the domain transform samples and its memory requirement, and column 412 shows the number of short-time samples and its memory requirement.

The FTA module iteratively adds outputs from the frequency transforms (FFT or DCT) and stores them as a vector as opposed to generating a large matrix to save memory. As discussed above, the final output of the FTA module is a mean frequency value that may be used by other modules or components of system 100, such as the approximate neighbor search accelerator 122. The mean frequency value may be provided to the module 102 via interconnect 104, may be output from the system 100 via data transfer through interconnect 104, and/or may be stored in the shared memory region 130.

### Kinetic Trajectory/Path Matrix Accelerator (KTMA)

Referring back to FIG. 1, the system 100 includes a kinetic trajectory/path matrix accelerator (KTMA) module 120. This module may be implemented in software (e.g., on a RISCV controller) or in digital logic similar to the FTA module construction discussed above. Once results from the FTA module 118 (e.g., a mean frequency value) are available in the shared memory region 130, the module 102 (e.g., a software state machine running on the CPU, such as a RISCV CPU) may initiate the KTMA computation. The state machine controller may be programmed with a data flow queuing that automatically triggers the execution of the next block upon receiving of a message or a COMPLETION signal from the block.

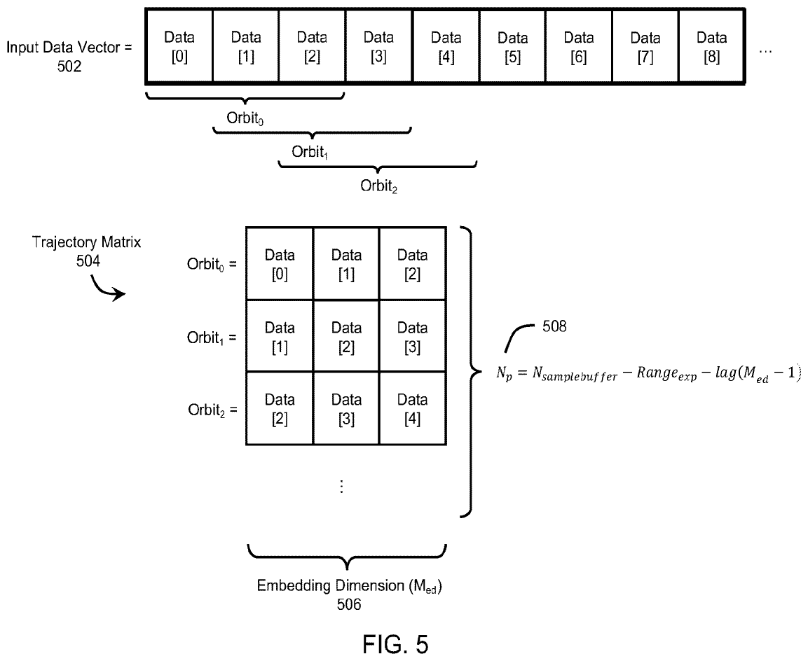

In the implementation, the KTMA 120 generates a trajectory matrix by re-arranging data from the sample space. An example of this process is shown in FIG. 5. An input data vector 502 is provided. The size of the trajectory matrix 504 generated from the input data vector 502 is determined by the embedded dimension 506 along a first dimension (e.g., defining the number of columns in the matrix 504) and by the number of orbits (Np) 508 in a second dimension (e.g., defining the number of rows in the matrix 504). An orbit is a vector composed from the indices of the data without allocating or saving the vector in a memory. The data is not copied to an array and saved; rather, the input data vector in the correct indices is accessed while calculations are being performed. An orbit may be constructed according to Equation 5.

$${Orbit}_{i} [ j ] = data [ i + lag \times j ] ; j = 0 … embedded dimension - 1. \qquad Eq . 5$$

The number of required orbits Np can be calculated according to Equation 6 below, where Rangeexp is an expansion range of the matrix, Med is the embedded dimension, and lag is a selected value (e.g., a value between 1-10) that determines whether, and how many, points of the original sample data are skipped when assembling orbits for matrix 504.

$${N}_{p} = {N}_{samplebuffer} - {Range}_{exp} - lag ( {M}_{e d} - 1 ) . \qquad Eq . 6$$

The embedding dimension 506 may be selected prior to initiating the KTMA module. In the example of FIG. 5, the embedding dimension 506 is three; however, different values may be selected depending on the complexity of the parameters being calculated or the system being characterized. The embedded dimension may be an integer (e.g., between 3-12 or between 6-10). In some embodiments, the embedded dimension may be 8 or 10.

Alternatively, rather than pre-selecting an embedding dimension value, an algorithm may be used to estimate the minimum embedding dimension. The embedding dimension estimation algorithm may include a False Nearest Neighbor (FNN) algorithm that may be used in the phase space reconstruction.

The lag variable determines how many data points from the sample buffer (Nsamplebuffer) 502 are skipped when populating the trajectory matrix, and the lag value may be a pre-determined integer value. The number of data points skipped when generating orbits within the trajectory matrix may be equal to (lag-1). Thus, in the example of FIG. 5 where the lag value is set to 1, no data points are skipped while generating the orbits.

In some embodiments, the optimal lag may be estimated using Average Mutual Information (AMI), which is an algorithm that runs within the phase space reconstruction (i.e., the trajectory matrix generator 120). In order to estimate the optimal lag, a range of lag values (e.g., 1, 2, . . . , 10) is selected and a trajectory matrix may be generated for each of the lag values in the selected range. Once the trajectory matrices are generated, the AMI may be calculated using Equation 7. The lag value associated with the minimum AMI may be identified and used as the selected lag value.

$$AMI ( lag ) = {\sum }_{i = 0}^{N} p ( {x}_{i} , {x}_{i + l a g} ) {log}_{2} [ \frac{p ( {x}_{i} , {x}_{i + lag} )}{p ( {x}_{i} ) p ( {x}_{i + lag )}} ] . \qquad Eq . 7$$

Expansion range is an integer parameter describing how much of the sample data is included in the trajectory matrix and may be expressed as a percentage. For example, if an initial sample includes 20,000 data points and the expansion range is selected to be 30%, 6,000 data points will be included in the trajectory matrix. Continuing this example, if an embedded dimension is selected to be 10 and a lag value is selected to be 1, the number of orbits Np may be calculated as shown in Equation 8 which is based on the relationships described by Equation 6.

$${N}_{p} = ( 20 , 000 ) - 0.3 ( 20 , 000 ) - 1 ( 10 - 1 ) = 13 , 991. \qquad Eq . 8$$

The expansion range is also utilized later when determining the evolution over time of the nearest neighbors based on integer time steps up until a maximum time step difference (i.e. expansion range).

Thus, generation of a trajectory matrix may be simplified by rearranging data samples as illustrated in FIG. 5. Additional simplifications include setting up certain actions (e.g., access to the matrix, access to the data array, calculation of correct indexes) such that they require a constant amount of time for completion (e.g., O(1)). In some embodiments, the trajectory matrix is not saved and is not populated/stored all at once; rather, two or more orbits may be generated at a time and a nearest neighbor search between the orbits may be completed. In this way, the matrix may be generated and analyzed dynamically rather than all at once in order to reduce the amount of memory required by the computation.

Alternate methods of finding a kinetic path or trajectory may use Covariance matrices or a Dijkstra method of shortest path computation.

Approximate Nearest Neighbor Search (kNN) Accelerator (kNNA)

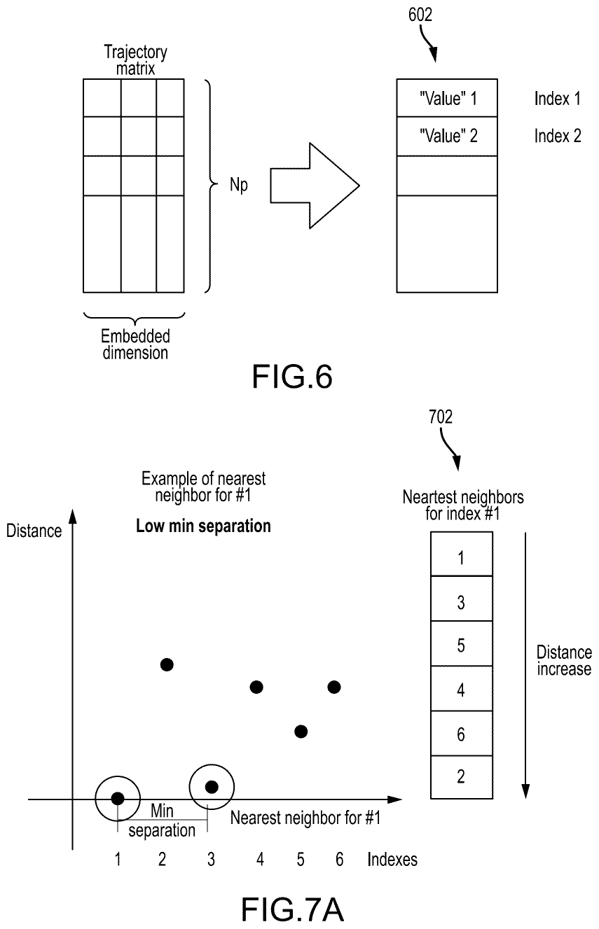

The Approximate Nearest Neighbor Search Accelerator (kNNA) 122 may be implemented as a 1-nearest neighbor search rather than a K-nearest neighbor search. As discussed above, each orbit in the trajectory matrix has a size determined by the embedded dimension. For each of the orbits, the 1-nearest neighbor algorithm searches K nearest neighbors (e.g., in terms of Euclidean distance as calculated by the Euclidean and Affine Accelerator 124), where K, in the worst case, is equal to the number of points (Np) (i.e., searching an entire trajectory matrix). For each orbit, an array of distances to the other orbits is generated and indexed in an array 602 as shown in FIG. 6, where “values” represent distances. The distances are then sorted (e.g., from minimum distance to maximum distance).

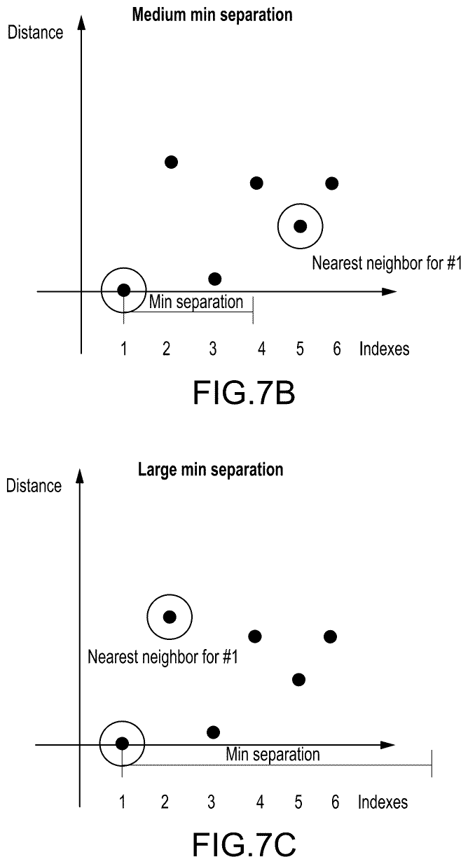

FIG. 7A shows the nearest neighbor array 702 for Orbit 1 as an example, with Orbits 3, 5, 4, 6, and 2 increasing in distance from Orbit 1. In some embodiments, the time complexity is

$$O ( {N}_{p}^{2} log {N}_{p} )$$

and space is

$$O ( {N}_{p}^{2} )$$

as the distance matrix is being saved.

For each orbit, the index associated with the orbit having the smallest distance (i.e., the nearest neighbor) is compared with a minimum separation parameter (“min separation”). If the index associated with the nearest neighbor (e.g., Index 3 in the example shown in FIG. 7A) is larger than the minimum separation threshold for the indices, the nearest neighbor is returned. However, if the index for the nearest neighbor is smaller than the minimum separation as shown in the example of FIG. 7B, the second nearest neighbor is evaluated (e.g., Index 5). If the second nearest neighbor distance is greater than the minimum separation, it is returned. If it is too close, the third nearest neighbor is evaluated, and so on. If all the indexes associated with K nearest neighbors are smaller than the minimum separation, the farthest (i.e., in terms of distance) of the K neighbors is returned, as illustrated in the example of FIG. 7C. The minimum separation parameter may be calculated according to Equation 9, where the “mean frequency” is provided by the FTA module 118.

$$min separation = round ( 1 / mean frequency ) . \qquad Eq . 9$$

In some embodiments, the single nearest neighbor search (i.e., a nearest neighbor search between two orbits) time complexity is O(1) in space. In contrast, a nearest neighbor search for the entire trajectory matrix has a time complexity

$$O ( {N}_{p}^{2} )$$

and Space complexity is O(Nₚ).

### Euclidean and Affine Accelerator (EAA)

Referring back to FIG. 1, the Euclidean and Affine Accelerator (EAA) 124 is a hardware accelerator (co-processor) used to compute Euclidean and Affine distances between two vectors or orbits. These distance calculations may be used to complete the nearest neighbor searching between orbits within the KNNA module 122. The Euclidean distances that can be computed can be standard distance, D=|a-b| from a first element (a) to a corresponding element (b), or can be a distance given by Equation 10.

$$D ( i , j ) = \sqrt{{{\sum }_{k = 0}^{embedded dimension - 1} {( orbit}_{i} [ k ] - {orbit}_{j} [ k ] )}^{2}} . \qquad Eq . 10$$

Other distances that can be computed are also called Maximum Metric Distances such as Chebyshev, Manhattan, Diamond, Cosine, Hamming, Minkowski, Haversine, Jaccard Distance, and Sorensen Dice. In some embodiments, different types of distance calculations may be performed depending on the parameter being computed. For example, when seeking to compute a RVES index, a different distance calculation may be used than when seeking to compute reduced-complexity correlation dimension. Information associating each parameter calculation with a specific method for nearest neighbor distance calculation may be stored within the system 100 for access when a parameter is being calculated.

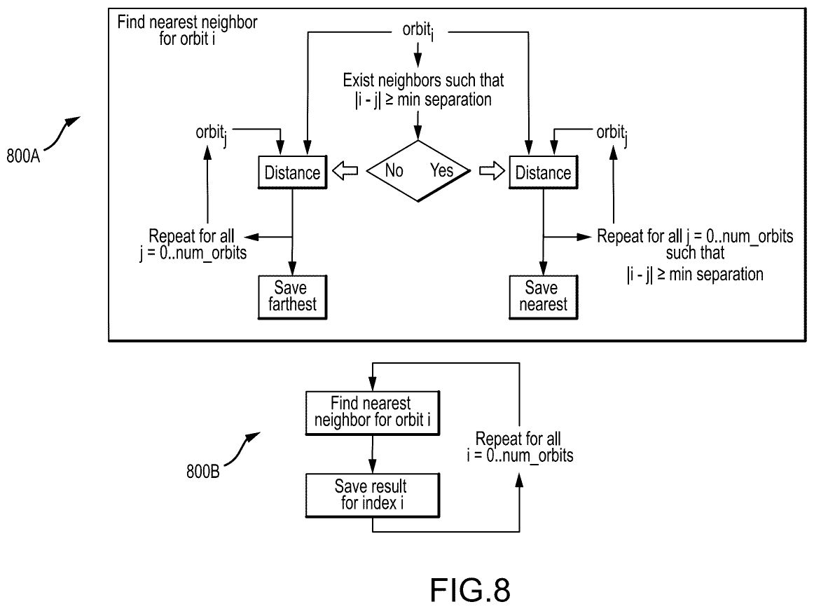

FIG. 8 is a block diagram illustrating a process 800A for calculating a distance between two orbits or vectors (e.g., orbits or vectors i and j) for the KNNA 124 and a process 800B for storing the nearest neighbor for each orbit.

### Cordic and Non-Linear Function Accelerator (CNFA)

Referring to FIG. 1, the Cordic and Non-linear Function Accelerator (CNFA) 126 supports functions including absolute values of complex-valued vectors, cosine and inverse cosine, sine and inverse sine, tangent (tanh), hyperbolic sine and cosine, reciprocals, square roots, sigmoid, logarithmic, and eigen value estimations. One or more of these functions may be used during the calculation of parameters or during the calculation of other variables. For example, the CNFA 126 may be used during calculation of the mean frequency, which is a reciprocal operation.

Additionally, a log distance function may be used when the state machine now checks how much “close” states differ as the time advances in order to measure the electrodynamics of the cell. This is achieved by taking each orbit and its nearest neighbor, advancing them in time, up until a maximum time (i.e. expansion range) and calculating the distance between them. Since this operation deals with exponents, a natural log of the distances provides a meaningful measurement. For each time advancement, an average of the log distance of all the orbits may be saved.

### Direct Memory Access (DMA) Accelerator

The Direct Memory Access (DMA) accelerator 128 (FIG. 1) holds descriptor information along with channel information. The DMA accelerator 128 uses one AHB Lite target interface to initialize and update the descriptor table contained in this DMA IP and one

AHB Lite Initiator interfaces to transfer the blocks of DMA one for the source side and one for the destination side.

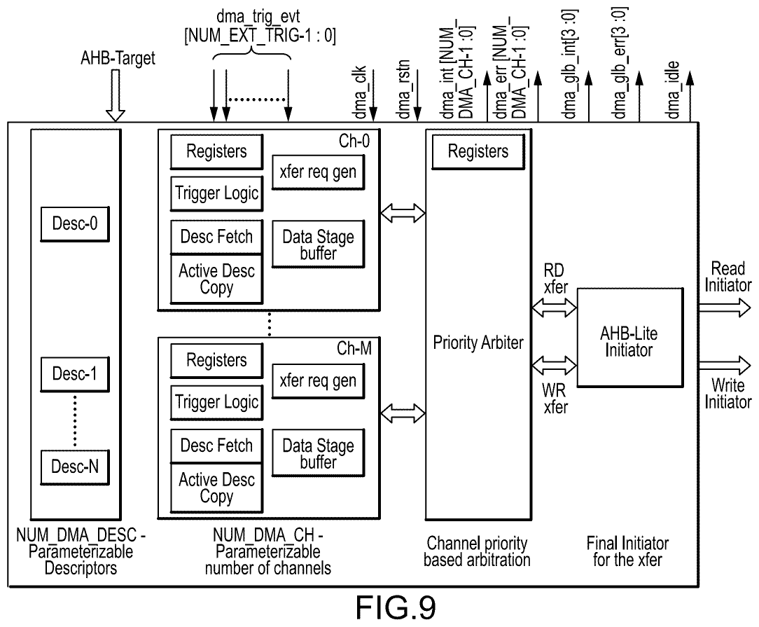

In the block diagram shown in FIG. 9, the DMA accelerator accesses descriptor information and control information through the AHB lite target. Once the descriptor table is initialized, the AHB Processor master writes the control information that enables the DMA transfer. The selected channel then arbitrates for the descriptor table, and once accessed, the selected channel copies descriptor information to local registers. Each channel strips corresponding fields of the descriptor information and learns the source address, destination address, read/write and corresponding nature of the DMA transfer.

In some embodiments, the DMA accelerator can support Aug. 16, 1932-bit reads/writes. The DMA accelerator may be initiated by the RISCV CPU that controls the overall state machine to fetch or transfer data from the Shared Memory SRAM.

### Shared Memory Region (SMR)

The shared memory region (SMR) 130 in FIG. 1 may be a 64 KB-128 KB dual ported, 4-bank memory system used as a Level 2 memory to transfer data from the system controller through the AHB interconnect or vice-versa after the computation is performed by the accelerator. Other configurations of the SMR are possible depending on the number and type of accelerators and on the type and amount of data being processed. In addition to the SMR 130, one or more of the accelerator modules 118-128 may also have an internal register and/or local memory that may be used to perform operations.

### State Machine Controller (RISCV)

The state machine that runs in software uses the underlying accelerators (i.e., one or more of modules 118-128) to compute electrodynamic parameters in real time and perform true computational electrodynamics. The RISCV system works in a slave mode and may be triggered through an interrupt or message passing mutex that in turn then triggers the DMA 128 to transfer the data to the desired location in the SMR 130.

As discussed above, electrodynamic parameters that may be calculated using one or more of the accelerator modules described herein include Residual Vector Energy Separation Index (RVES), Reduced Complexity Correlation Dimension (RCCD), Dynamic Sample Entropy (DSE), and/or Dispersional Analysis-based Hurst Exponent (DAHE), Detrended Fluctuation Analysis (DFA), and Charge Rate Voltage Slew (DIDVS). In some embodiments, calculation of the RVES relies on all accelerator modules described. Calculation of the RCCD and the DSE may rely on the KTMA 120, EAA 124, and CNFA 126 modules. Calculation of the DAHE and DFA may rely on the EAA 124 and CNFA 126 modules.

Thus, it can be seen that the number and type of accelerator module that should be included within an accelerator system is dependent upon the parameters being calculated. Systems are contemplated herein that include a subset of all accelerator modules described. For example, a system is contemplated that includes KTMA 120, EAA 124, and CNFA 126 modules such that RCCD, DSE, DAHE, and DFA can be calculated; however, because the FTA module is omitted, calculation of the RVES parameter may not be performed by this system.

In some embodiments, determining the Residual Vector Energy Separation Index includes calculating a slope of a linear equation using ordinary least squares fit. This approach may be beneficial when working with data that contains noise. The linear equation is described by Equation 11.

$$average log distance = a \times time expansion index . \qquad Eq . 11$$

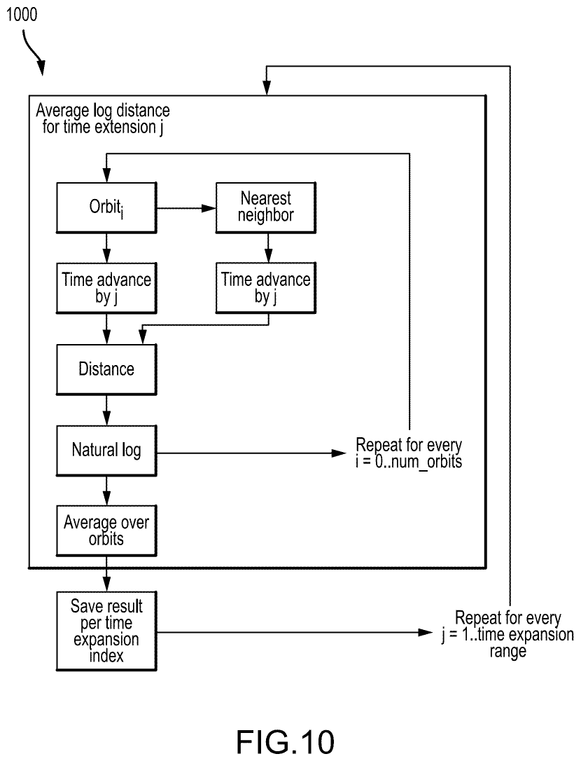

The time expansion, shift, or advancement all refer to how an orbit behaves when its time index is advanced. Time expansion is described in block diagram 1000 of FIG. 10 and by Equation 12.

$$time expansion ( expansion index , {orbit}_{i} ) = {orbit}_{i + expansion , index} . \qquad Eq . 12$$

### Characterization Waveform

The system 100 may trigger the need to drive a certain characterization signal from module 102 (e.g., the RISCV CPU) whose parameters are already stored in a lookup table in the memory based on State of Charge (SoC), State of Health (SoH), and/or other parameters.

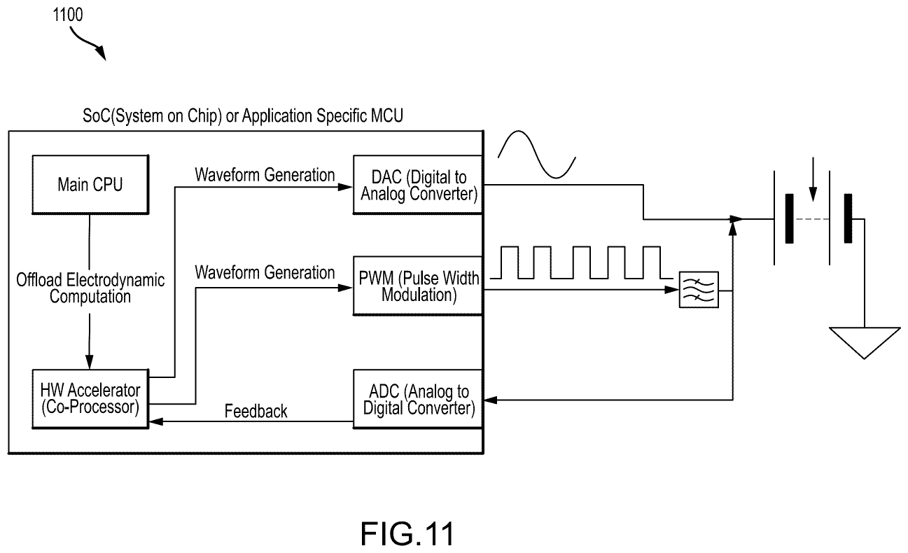

The state machine triggers the DMA to send the ADC samples of Current (I) and Voltage (V) or other information from the battery or electrochemical system from the charge circuit which has been captured to the local memory of the application-specific processor, MCU or a chiplet. The feedback system is developed as shown in the block diagram 1100 of FIG. 11. The system includes a software state machine that generates the desired or commandeered current (I) samples that are transferred to a Charge controller through the AHB Interconnect to steer the current sent to the battery device or other signals in electrochemical systems.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance”, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

What is claimed is:

1. A system for calculating an electrodynamic parameter of a battery, the system comprising:
at least one co-processor module in operable communication with a state machine controller,
wherein the at least one co-processor module is configured to perform a specific mathematical or logical operation that is used to calculate the electrodynamic parameter of the battery.

2. The system of claim 1, wherein the at least one co-processor module comprises a frequency transform accelerator configured to calculate a mean frequency or an energy from a data sample.

3. The system of claim 1, wherein the at least one co-processor module comprises a kinetic trajectory/path matrix accelerator configured to generate a trajectory or a path matrix from the data sample, wherein the trajectory matrix comprises a plurality of orbits, and wherein the data sample comprises at least one vector.

4. The system of claim 3, wherein the at least one co-processor module comprises a neighbor search co-processor configured to determine at least one of a nearest neighbor and a furthest neighbor for one of the plurality of orbits of the trajectory matrix.

5. The system of claim 4, wherein the neighbor search co-processor comprises an approximate neighbor search co-processor.

6. The system of claim 4, wherein the neighbor search co-processor comprises a k-neighbor search co-processor.

7. The system of claim 4, wherein the neighbor search co-processor is configured to return the nearest neighbor when a minimum separation threshold is satisfied.

8. The system of claim 4, wherein the approximate neighbor search co-processor is configured to return the furthest neighbor when the minimum separation threshold is not satisfied.

9. The system of claim 1, wherein the at least one co-processor module comprises a Euclidean and affine co-processor configured to calculate a distance between orbits.

10. The system of claim 7, wherein the Euclidean and affine co-processor is configured to calculate the distance using a distance calculation associated with the electrodynamic parameter of the battery being calculated.

11. The system of claim 1, wherein the at least one co-processor module comprises a cordic and non-linear function co-processor configured to calculate an inverse function.

12. The system of claim 9, wherein the inverse function is a mean frequency value.

13. The system of claim 1, wherein the at least one co-processor module comprises a direct memory access co-processor configured to transfer information to a shared memory region.

14. The system of claim 1, wherein the at least one co-processor module is in communication with the shared memory region.

15. The system of claim 1, wherein the electrodynamic parameter of the battery comprises at least one of a residual vector energy separation index, a reduced-complexity correlation dimension score, a dynamic sample entropy index, a dispersional analysis-based Hurst exponent score, a detrended fluctuation analysis index, and a charge rate voltage slew score.

16. The system of claim 1, wherein at least two of the co-processor modules are in communication with each other and are configured to pass information therebetween to calculate the electrodynamic parameter.

17. The system of claim 1, wherein the state machine controller comprises at least one of a programmable logic and a central processing unit (CPU).

18. A method of generating a battery charging signal, the method comprising:
calculating an electrodynamic parameter of a battery using at least one co-processor module; and
generating a battery charging signal based on the electrodynamic parameter of the battery.

19. The method of claim 18, wherein the electrodynamic parameter of the battery comprises at least one of a residual vector energy separation index, a reduced-complexity correlation dimension score, a dynamic sample entropy index, a dispersional analysis-based Hurst exponent score, a detrended fluctuation analysis index, and a charge rate voltage slew score.
